(19) United States
(12) Patent Application Publication
(10) Pub. No.: US 2008/0233682 A1
(43) Pub. Date: Sep. 25, 2008

(54) METHODS OF FORMING A CORED METALLIC THERMAL INTERFACE MATERIAL AND STRUCTURES FORMED THEREBY

(76) Inventors: Daewoong Suh, Phoenix, AZ (US); Jessica Weninger, Chandler, AZ (US)

Correspondence Address: INTEL CORPORATION;c/o INTELLEVATE, LLC, P.O. BOX 52050, MINNEAPOLIS, MN, 55402, US

(21) Appl. No.: 11/688,629

(22) Filed: Mar. 20, 2007

(51) Int. Cl. H01L 21/00

(52) U.S. Cl. 438/122

(57) ABSTRACT

Methods and associated structures of forming a microelectronic device are described. Those methods may include forming a core portion of a TIM, wherein the core portion comprises a high thermal conductivity and does not comprise indium, and forming an outer portion of the TIM on the core portion.

### BACKGROUND OF THE INVENTION

Currently pure indium may be used as a thermal interface material (TIM). In some cases, the TIM may be used to attach a heat spreader and a silicon die during microelectronic packaging applications, for example. However, the price of raw indium has been skyrocketing in recent years. Thus, it is desirable to reduce the amount of indium in TIM applications to lower manufacturing cost.

### BRIEF DESCRIPTION OF THE DRAWINGS

While the specification concludes with claims particularly pointing out and distinctly claiming that which is regarded as the present invention, the advantages of this invention can be more readily ascertained from the following description of the invention when read in conjunction with the accompanying drawings in which:

FIGS. 1a-1h represent structures according to an embodiment of the present invention.

### DETAILED DESCRIPTION OF THE PRESENT INVENTION

In the following detailed description, reference is made to the accompanying drawings that show, by way of illustration, specific embodiments in which the invention may be practiced. These embodiments are described in sufficient detail to enable those skilled in the art to practice the invention. It is to be understood that the various embodiments of the invention, although different, are not necessarily mutually exclusive. For example, a particular feature, structure, or characteristic described herein, in connection with one embodiment, may be implemented within other embodiments without departing from the spirit and scope of the invention. In addition, it is to be understood that the location or arrangement of individual elements within each disclosed embodiment may be modified without departing from the spirit and scope of the invention. The following detailed description is, therefore, not to be taken in a limiting sense, and the scope of the present invention is defined only by the appended claims, appropriately interpreted, along with the full range of equivalents to which the claims are entitled. In the drawings, like numerals refer to the same or similar functionality throughout the several views.

Methods and associated structures of forming a microelectronic structure are described. Those methods may include forming a core portion of a thermal interface material (TIM), wherein the core portion comprises a high thermal conductivity and does not comprise indium, and forming an outer portion of the TIM on the core portion. Methods of the present invention enable the formation of a TIM comprising a lower cost core material that may serve as a volume occupier to reduce cost.

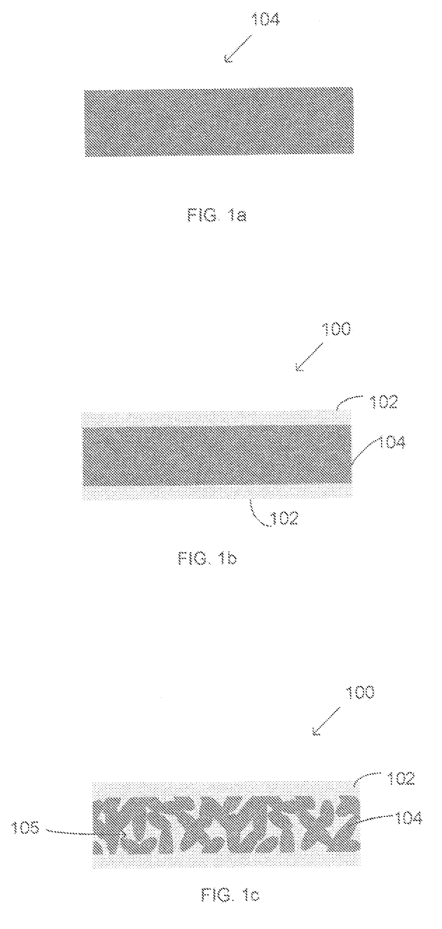

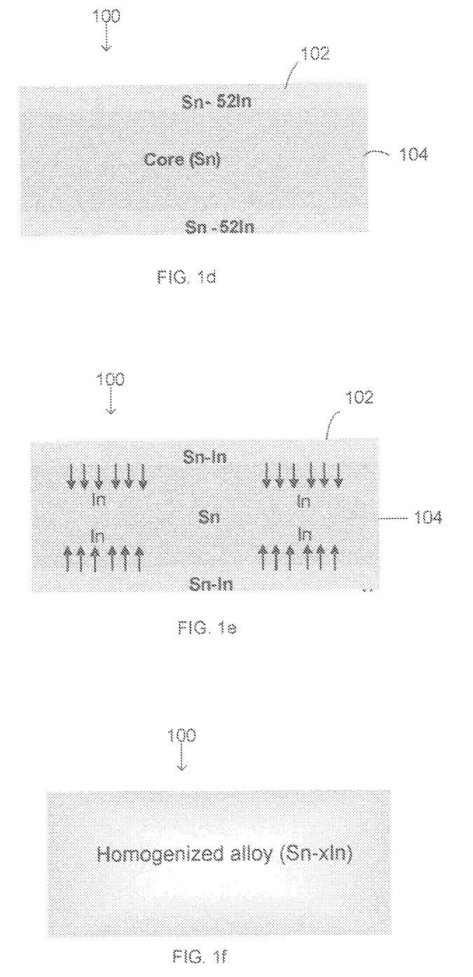

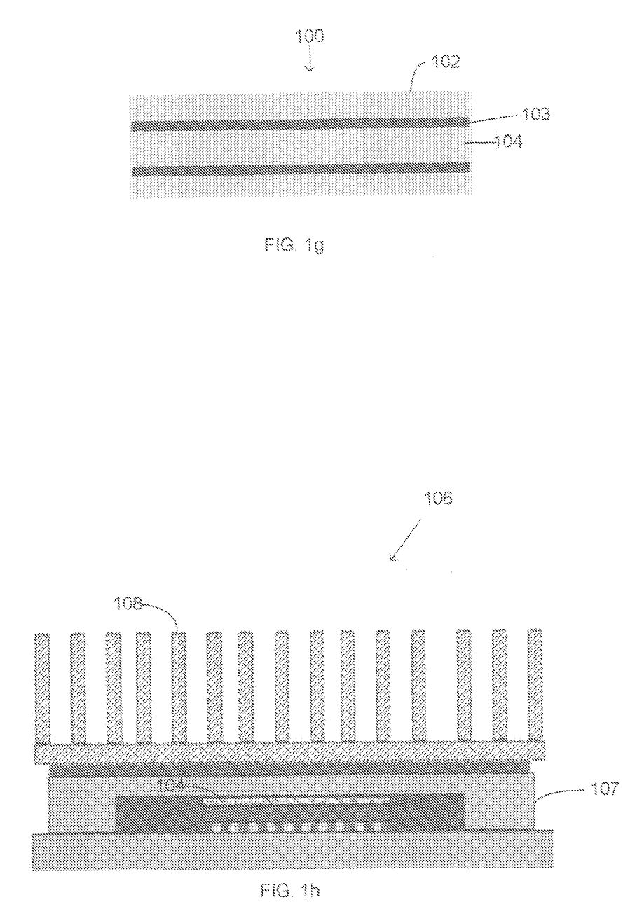

FIGS. 1a-1h illustrate embodiments of methods of forming a TIM 100. FIG. 1a illustrates a cross-section of a core portion 104 of a TIM 100. In one embodiment, the core portion 104 may comprise a high thermal conductivity and may not substantially comprise indium. In one embodiment, the core portion 104 may comprise at least one of copper, nickel, aluminum and silicon carbide and combinations thereof. In one embodiment, the core portion 104 may be a continuous core portion 104. In one embodiment, the continuous core portion 104 may be composed of a solid material with low cost and high thermal conductivity. In some embodiments, the core portion 104 may be produced by utilizing conventional sheet metal processes such as rolling, etc., as is known in the art.

In one embodiment, an outer portion 102 may be formed on the core portion 104 of the TIM 101 (FIG. 1b). In one embodiment, the outer portion 102 may comprise at least one of tin, indium, bismuth, silver, zinc, antimony and combinations thereof. In one embodiment, the outer portion 102 may be applied to the core portion 104 by utilizing an electroless and/or electrolytic plating, or a cladding process, such as by extruding metal sheets through a die or pressing them together under high pressure. In one embodiment, the outer portion 102 of the TIM 101 may comprise a wettable active layer that may form a metallic bond during a subsequent process, such as during a reflow process, as is known in the art, for example.

In one embodiment, the core portion 104 may comprise a discontinuous core portion 104 (FIG. 1c). In one embodiment, the discontinuous core 104 may comprise a composite material such as a low cost material and a solder alloy, such as copper, nickel, aluminum and silicon carbide and combinations thereof.

The discontinuous core portion 104 may be produced by making a porous preform of low cost metal, and may be formed from metal powders by cold compaction, sintering, or hot compaction, for example. In some embodiments, empty space within the discontinuous core portion 104 can be filled with a solder matrix material 105, by utilizing a liquid metal infiltration process, for example.

In one embodiment, the TIM 100 may comprise materials that change melting temperature after a undergoing a subsequent process temperature. For example, a transient liquid phase (or Phase Changing) system may be employed, in which the TIM 100 may comprise a low assembly temp and higher re-melting temperature after assembly. The particular materials employed in the transient liquid phase system may depend upon the particular application, but in general the liquid phase system may comprise materials that exhibit extensive solubility in each other and form little to no intermetallic compounds between the core portion and the outer portion 102. For example, in one embodiment, the core portion 104 of the TIM 100 may comprise a tin material, and the outer portion 102 may comprise a tin-indium alloy, such as but not limited to tin-52 indium (FIG. d).

In one embodiment, after the core portion 104 and the outer portion 102 have been assembled together (by various methods such as sheet rolling and pre-form utilization) the TIM 100 may undergo subsequent temperature processing, such as during a bonding process, for example (FIG. 1e). In one embodiment, the temperature of such a process may comprise between about 140 to about 160 degrees Celsius, but may vary depending upon the particular application.

During such a subsequent temperature process, the outer portion 102 may interdiffuse into the core portion 104. The interdiffusion of the outer portion material 102 may result in little to no intermetallic formation between the core portion 104 and the outer portion 102. After temperature processing, the TIM 100 may comprise a homogenized TIM alloy, which may comprise a higher melting temperature than before such temperature processing, due to phase changes that may occur within the TIM 100 (FIG. 1f). A higher melting temperature of the TIM 100 after a bonding process may serve to improve reliability of the TIM, and of a microelectronic structure utilizing the TIM.

In another embodiment, a reacting system may be employed, wherein the TIM 100 may comprise improved thermal conductivity, but may not substantially comprise increased melting temperature after subsequent thermal processing, as in the phase change system previously described. In one embodiment, the core portion 104 of the TIM 100 may comprise at least one of silver, copper, nickel, and other such high thermal conductivity materials. In one embodiment, the outer portion may comprise tin, indium or combinations thereof, for example. After temperature processing, an intermetallic 103 may be formed between the core portion 104 and the outer portion 102 of the TIM 100 (FIG. 1g). The intermetallic 103 may serve as diffusion barrier for higher temp cycling.

FIG. 1h depicts a package structure 106, wherein the TIM 100 may be disposed between a die 110 and a heat sink structure 108, and also may be disposed between a heat spreader structure 107 and the heat sink structure 108. The TIM 100 may comprise any of the TIM embodiments of the present invention. In one embodiment, the die 110 may comprise a silicon die, and the package structure 106 may comprise a ceramic package and/or an organic package structure.

Thus, the benefits of the embodiments of the present invention include, but are not limited to, utilizing a cored microstructure TIM material wherein the core portion comprises a low cost material. Such as low cost, high thermal conductivity material may serve as a volume occupier to reduce manufacturing cost. An optional matrix material within the core portion may serve as a binder or space filler for the low-cost core if desired. The outer portion may serve as a wettable active layer to form a metallic bond during a reflow process, for example.

Although the foregoing description has specified certain steps and materials that may be used in the method of the present invention, those skilled in the art will appreciate that many modifications and substitutions may be made. Accordingly, it is intended that all such modifications, alterations, substitutions and additions be considered to fall within the spirit and scope of the invention as defined by the appended claims. In addition, it is appreciated that certain aspects of microelectronic devices are well known in the art. Therefore, it is appreciated that the Figures provided herein illustrate only portions of an exemplary microelectronic structure that pertains to the practice of the present invention. Thus the present invention is not limited to the structures described herein.

What is claimed is:

1. A method of forming a TIM comprising:
forming a core portion of the TIM, wherein the core portion comprises a high thermal conductivity and does not comprise indium; and
forming an outer portion of the TIM on the core portion.

2. The method of claim 1 further comprising wherein the outer portion comprises at least one of tin, indium, bismuth, silver, zinc, antimony and combinations thereof.

3. The method of claim 1 further comprising wherein the core portion comprises at least one of copper, nickel, aluminum, silicon carbide and tin.

4. The method of claim 1 further comprising wherein the core portion comprises at least one of a continuous core portion and a discontinuous core portion.

5. The method of claim 1 further comprising wherein the core portion does not form an intermetallic with the outer portion, and undergoes a phase change upon application of an assembly temperature.

6. The method of claim 5 wherein the core portion comprises at least one of tin and a tin alloy.

7. The method of claim 6 further comprising wherein the outer portion comprises at least one of tin and indium.

8. The method of claim 1 further comprising wherein the core portion forms an intermetallic with the outer portion.

9. A TIM structure comprising:
a core portion, wherein the core portion comprises a high thermal conductivity and does not comprise indium; and
an outer portion disposed on the core portion.

10. The structure of claim 9 wherein the outer portion comprises at least one of tin, indium, bismuth, silver, zinc, antimony and combinations thereof.

11. The structure of claim 9 wherein the core portion comprises at least one of copper, nickel, aluminum, silicon carbide, tin and combinations thereof.

12. The structure of claim 9 wherein the core portion comprises at least one of a continuous core portion and a discontinuous core portion.

13. The structure of claim 9 wherein the core portion does not comprise an intermetallic with the outer portion.

14. The structure of claim 9 wherein the core portion comprises an intermetallic with the outer portion.

15. The structure of claim 9 further comprising wherein the TIM is disposed between a die and a heat sink structure.
